(19) United States
(12) Patent Application Publication
(10) Pub. No.: US 2004/0226398 A1
(43) Pub. Date: Nov. 18, 2004

(54) Adjustable pedal mechanism

(76) Inventors: Andree Burgstaler, Dielingen (DE); Jan Dutz, Damme (DE); Simone Parke, Osnabruck (DE)

Correspondence Address: McGLEW AND TUTTLE, P.C., SCARBOROUGH STATION, SCARBOROUGH, NY, 10510-0827, US

(21) Appl. No.: 10/819,495

(22) Filed: Apr. 7, 2004

(30) Foreign Application Priority Data
Apr. 8, 2003 (DE) DE 103 16 309.6

(51) Int. Cl. H05K 1/00

(52) U.S. Cl. 74/512

(57) ABSTRACT

A device is provided for adjusting a connecting piece (3) that is mounted rotatably by a mounting arrangement (11), especially a pedal mechanism in a motor vehicle, which is coupled with a transmission unit (5) for transmitting the movement of the connecting piece (3). The device includes an adjusting mechanism (12) for adjusting the position of the connecting piece (3), a blocking unit, which prevents the unintended adjustment of the position of the connecting piece (3), and compensating device (4) for compensating any changes that may be caused in the position of the transmission unit (5) by the adjustment of the connecting piece (3). The mounting means (11) comprises a first, lower baseplate (1), which is arranged stationarily, and a second, upper baseplate (2), as well as an adjusting mechanism, which establishes an articulated connection (8) between the two baseplates (1 and 2). The second, upper baseplate (2) is mounted pivotably on the first, lower baseplate (1), and the second, upper baseplate (2) brings about an adjustment of the connecting piece (3) mounted in the mounting means (11) after the release of the blocking unit and/or during the actuation of a drive unit (9).

### CROSS REFERENCE TO RELATED APPLICATIONS

This application claims the benefit of priority under 35 U.S.C. § 119 of German patent application DE 103 16 309.3 filed Apr. 8, 2003 the entire contents of which are incorporated herein by reference.

### FIELD OF THE INVENTION

The present invention pertains to a device for adjusting a connecting piece mounted rotatably by means of a mounting means, especially a pedal mechanism in a motor vehicle, with which a transmission unit for transmitting the movement of the connecting piece is coupled, comprising an adjusting mechanism for adjusting the position of the connecting piece, a blocking unit, which prevents the unintended adjustment of the position of the connecting piece, and compensating means for compensating any changes that may occur in the position of the transmission means that may be caused by the adjustment of the connecting piece.

### BACKGROUND OF THE INVENTION

Such devices are usually used in motor vehicles, especially in passenger cars, for adjusting control pedals such as brake, clutch and gas pedals. Even though many components, such as the seat, the steering wheel, etc., can already be individually adjusted in passenger cars corresponding to the dimensions of the operator's body, solutions for adjusting one of the most frequently used components of the vehicle, the pedals, are uncommon. However, to guarantee an optimal adaptation of the vehicle to the individual and different dimensions of the bodies of the different drivers, it is also necessary to make the pedals individually adjustable corresponding to ergonomic ideas and guidelines and thus to guarantee fatigue-free and safe driving. Moreover, adjustability of the pedals is also meaningful concerning an optimal distance between the driver and the driver's side air bag.

The Offenlegungsschrift DE 100 26 751 A1 describes a solution in which the translatory and/or rotatory adjustment of a connecting piece that is of interest here is achieved by means of a separate adjusting mechanism, wherein separate compensating means essentially compensate the change in the position of the transmission unit resulting from the adjustment of the connecting piece.

The drawback occurring with the prior-art device is that a plurality of components or parts are needed for the adjustment of the connecting piece. In particular, the assembly of the separate compensating means is complicated, and these means are rather bulky.

### SUMMARY OF THE INVENTION

The object of the present invention is therefore to provide a device of the type described in the introduction, in which the connecting pieces are adjustable both together and one by one, i.e., individually, the adjusting mechanism has the most compact design possible because of the limited space required for its installation, and it is easy to operate, and the compensating means, which should leave the position of the transmitting unit nearly unchanged after the adjustment, should likewise be as compact and simple as possible.

According to the invention, the object is accomplished with a device for adjusting a connecting piece mounted rotatably by means of a mounting means, especially a pedal mechanism in a motor vehicle, with which a transmission unit is coupled for transmitting the movement of the connecting piece. An adjusting mechanism is provided for adjusting the position of the connecting piece. A blocking unit prevents the unintended adjustment of the position of the connecting piece. A compensating means is provided for compensating any changes in the position of the transmission unit that may be caused by the adjustment of the connecting piece. The mounting means comprises a first, lower baseplate, which is arranged stationarily, and a second, upper baseplate, as well as an adjusting mechanism, which establishes an articulated connection between the two baseplates. The second upper baseplate is mounted pivotably on the first lower baseplate. The second, upper baseplate brings about an adjustment of the connecting piece mounted in the mounting means after the release of the blocking unit and/or on actuation of a drive unit.

This solution offers the advantage that the adjusting mechanism is integrated in the mounting means and the compensating device in the connecting piece. It is thus guaranteed that no additional space is needed for the installation of separate components, and the device thus has an extremely compact design. Moreover, the need for a great assembly effort is eliminated, so that the cost of manufacturing the device is ultimately reduced as well. The first baseplate is advantageously arranged stationarily.

The connecting piece may be a pedal of a motor vehicle. However, it is also conceivable to use the device according to the present invention within the framework of other applications.

It is particularly advantageous for the transmission unit to be designed as a push rod, which is connected with the connecting piece via a bolt and is guided linearly in the upper, second baseplate such that the push rod follows the movement of the upper, second baseplate. It is thus possible to mount the push rod optimally to follow the movement of the connecting piece.

Provisions are made in one measure that improves the present invention for the compensating means to be designed as an elongated hole, which is made integrally in one piece with the connecting piece and ensures the angle compensation between the transmission unit and the connecting piece. A compensating means integrated within the connecting piece can thus be embodied in a compact form and at a low cost.

Provisions are made in another measure that improves the present invention for both one connecting piece and a plurality of connecting pieces to be able to be mounted on the first baseplate. As a result, each connecting piece can be set individually, and it is also possible to adjust all connecting pieces together.

The upper, second baseplate may be advantageously moved manually and/or mechanically after the release of the blocking unit. It is thus possible both to automate the adjusting mechanism and adjust it manually in case of safety, so that reliable and permanently available actuation is guaranteed.

Moreover, it is advantageous that the blocking unit is embodied by means of a positive-locking and/or nonpositive self-locking of the drive unit. The blocking means can thus be integrated in the drive unit, as a result of which the entire device requires less space for its installation.

A further improvement is represented by the fact that the adjustment of the upper, second baseplate is performed by means of a drive unit, which moves the upper, second baseplate in relation to the lower, first baseplate either directly via a spindle drive or indirectly via a spindle drive, which is followed by a force amplifier, for example, a wedge. It is thus possible to integrate adjusting members of a compact design, which can also be driven via a central control, in the adjusting unit. The individual adjusting members may be actuated individually or together, so that the connecting pieces can be set together or separately, individually.

In that the movement of the upper, second baseplate is performed in relation to the lower, first baseplate via a pivot bearing, the result is achieved that a small tilting mechanism is integrated between the two baseplates, which produces the desired adjustment of the connecting piece a simple manner.

Further advantageous embodiments are explained in greater detail on the basis of the figures. The various features of novelty which characterize the invention are pointed out with particularity in the claims annexed to and forming a part of this disclosure. For a better understanding of the invention, its operating advantages and specific objects attained by its uses, reference is made to the accompanying drawings and descriptive matter in which a preferred embodiment of the invention is illustrated.

### BRIEF DESCRIPTION OF THE DRAWINGS

FIG. 1 is an isometric view of the device for adjusting a connecting piece that is mounted rotatably by means of a mounting means;

FIG. 2 is a side view of the device according to FIG. 1;

FIG. 3 is a top view of the device according to FIG. 1;

FIG. 4 is a sectional view A-A of the device according to FIG. 3; and

FIG. 5 is another sectional view B-B of the device according to FIG. 3.

### DESCRIPTION OF THE PREFERRED EMBODIMENT

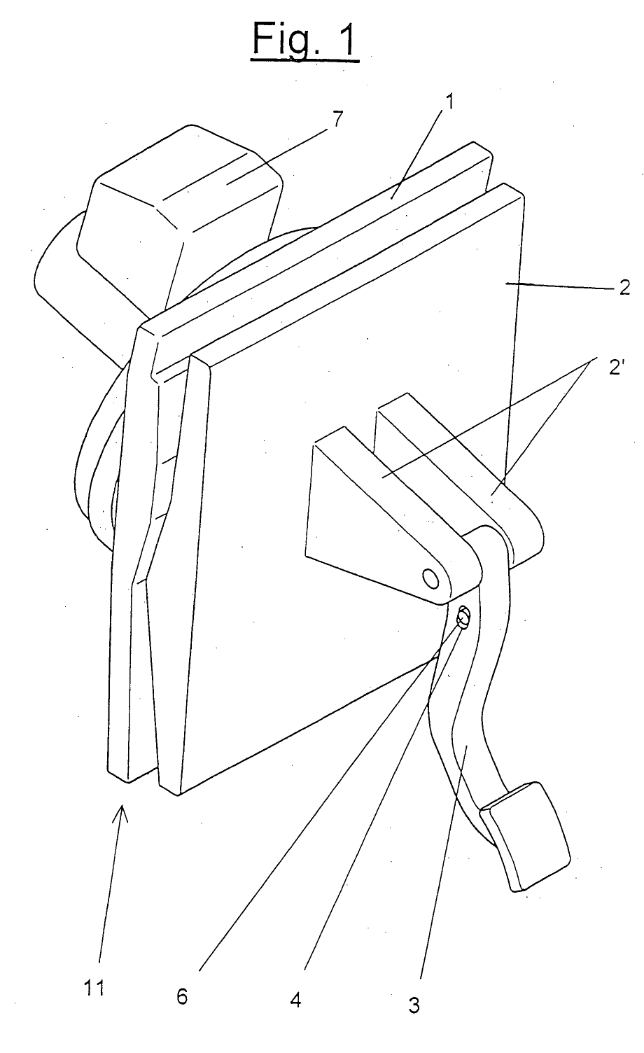

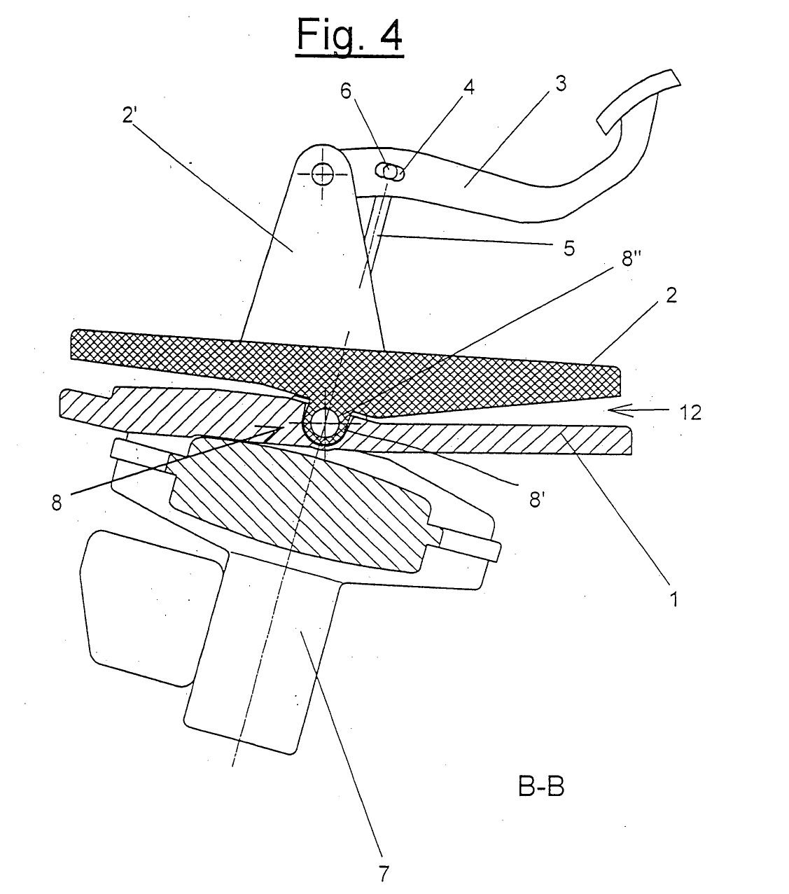

FIG. 1 shows a first, lower baseplate 1, on which a second, upper baseplate 2 is located. The two baseplates 1, 2 are connected to one another in an articulated manner. The second, upper baseplate 2 has centrally two elevations 2′ located at spaced locations from one another. The connecting piece 3 is mounted pivotably between these elevations 2′. The connecting piece 3 has integrated a compensating means 4 in the form of an elongated hole. The transmission unit 5 (better recognizable in FIG. 4), designed as a setbolt, is coupled with this compensating means 4 via a connector 6, which is mounted movably in the elongated hole and is preferably designed as a bolt. The force transmission unit 7 connected with the transmission unit 5 is located under the first, lower baseplate 1.

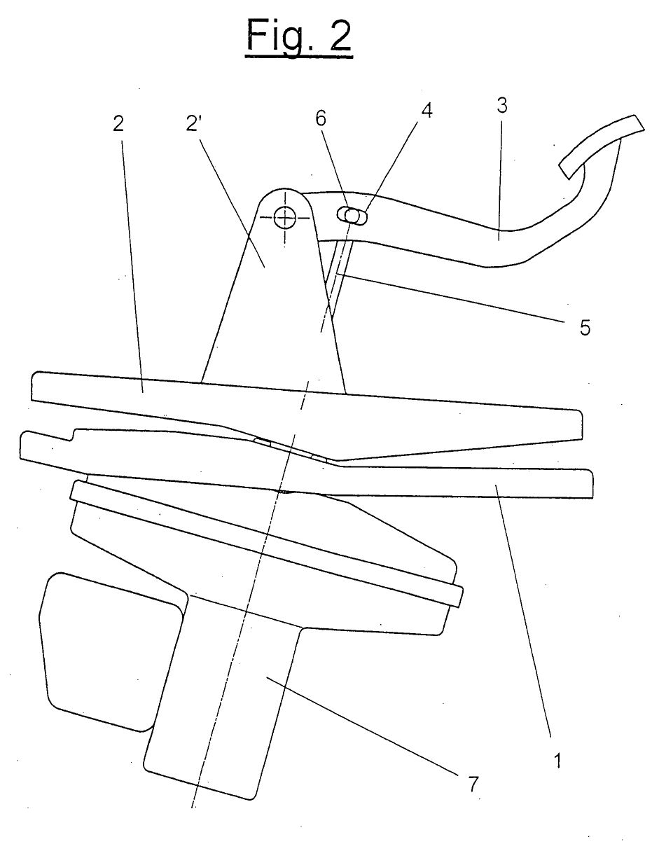

FIG. 2 shows the side view of the design of the device. The first, lower baseplate 1, on which the second, upper baseplate 2 is mounted tiltably, is located above the force transmission unit 7. The second, upper baseplate 2 has at least one elevation 2′ for mounting the connecting piece 3. The connecting piece 3 is mounted rotatably in a recess of the elevation 2′, preferably by means of a bolt connection. The transmission unit 5, designed as a setbolt, is placed between the force transmission unit 7 and the connecting piece 3 in the extension of the axis extending centrally through the force transmission unit 7. The transmission unit 5 has a connector 6, preferably in the form of a bolt, which is rigidly connected with the transmission unit 5. The connector 6 is mounted movably in the compensating means 4 integrated within the connecting piece 3, so that the compensating means 4 guarantee the guiding of the connector 6.

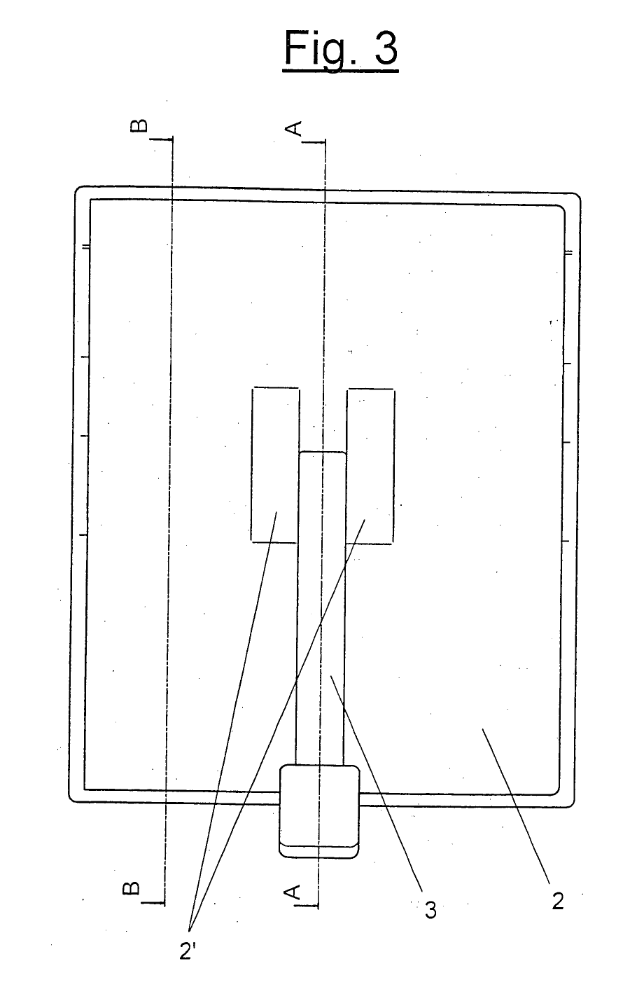

FIG. 3 shows the arrangement of the connecting piece 3 between the elevations 2′ of the second, upper baseplate 2. The connecting piece 3 is arranged in an accurately fitting manner between the two elevations 2′. The arrangement of the elevations 2′ and consequently the mounting of the connecting piece 3 designed as a pedal are embodied such that the movement of the connecting piece 3 is not inhibited, compromised or hindered during the actuation.

FIG. 4 shows the section B-B indicated in FIG. 3. FIG. 3 essentially corresponds to the view in FIG. 2. However, the connection 8 between the first, lower baseplate 1 and the second, upper baseplate 2 can be recognized more clearly in FIG. 4. The first, lower baseplate 1 has a recess 8′, in which an elevation 8″ of the second, upper baseplate 2 is mounted. The elevation 8″ of the second, upper baseplate 2 has a hole, and the recess 8′ of the first, lower baseplate 1 has a pin. The elevation 8″ of the second, upper baseplate 2 is connected with the recess 8′ of the first, lower baseplate 1 such that the hole of the elevation 8″ of the second, upper baseplate 2 surrounds the pin of the recess 8′ of the first, lower baseplate 1 in a positive-locking manner, doing so in such a way that the second, upper baseplate 2 can be moved around the pin of the recess 8′ of the first, lower baseplate 1. The movement of the second, upper baseplate is limited on both sides by the respective surfaces of the baseplates 1, 2.

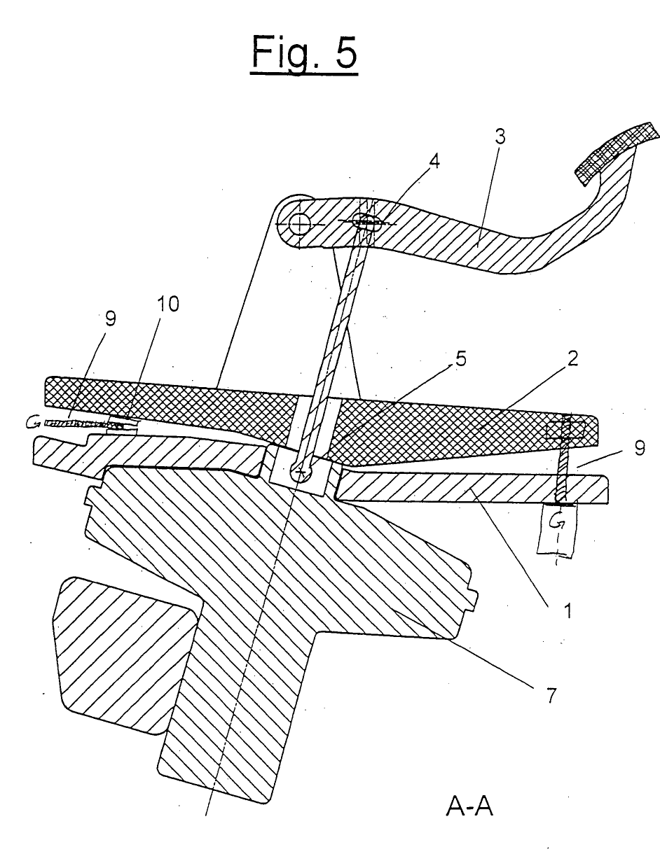

In addition to FIG. 4, FIG. 5 shows the connection between the transmission unit 5 designed as a setbolt and the force transmission unit 6 as well as two drive units 9 for the mechanical adjustment of the second, upper baseplate 2 and consequently of the connecting piece 3. The transmission unit 5 has a spherical end on the side facing the force transmission unit 7. This end is mounted movably in a recess of the force transmission unit. To allow a corresponding movement of the transmission unit 5, the second, upper baseplate 2 has a recess in the form of a hole. This hole permits the transmission unit 5 to follow the adjustment of the second, upper baseplate 2 to a limited extent. A drive unit 9 each, designed as a spindle unit, is arranged on both sides laterally between the two baseplates 1, 2. The spindle transmits the force needed for the adjustment of the second, upper baseplate 2 directly to the second, upper baseplate 2, on the one hand, and, on the other hand, the drive unit 9, designed as a spindle unit, indirectly drives a force amplifier 10, e.g., a wedge mechanism, which transmits the force to the second, upper baseplate 2.

While a specific embodiment of the invention has been shown and described in detail to illustrate the application of the principles of the invention, it will be understood that the invention may be embodied otherwise without departing from such principles.

### APPENDIX

List of Reference Numbers

1 First, lower baseplate

2 Second, upper baseplate

2′ Elevation

3 Connecting piece

4 Compensating means

5 Transmission unit

6 Connector

7 Force transmission unit

8 Connection

8′ Recess

8″ Elevation

9 Drive unit

10 Force amplifier

11 Mounting means

11 Adjusting mechanism

What is claimed is:

1. A device for adjusting a connecting piece mounted rotatably by means of a mounting means of a pedal mechanism in a motor vehicle with a transmission unit coupled for transmitting the movement of the connecting piece, the device comprising:
an adjusting mechanism for adjusting the position of the connecting piece;
a blocking unit preventing an unintended adjustment of the position of the connecting piece;
a compensating means for compensating any changes in the position of the transmission unit that may be caused by the adjustment of the connecting piece, said mounting means including a first, lower baseplate, which is arranged stationarily, a second, upper baseplate and said adjusting mechanism, which establishes an articulated connection between said first baseplate and said second baseplate, wherein said second baseplate is mounted pivotably on said first baseplate, and said second baseplate brings about an adjustment of the connecting piece mounted in the mounting means after the release of a blocking unit and/or on actuation of a drive unit.

2. A device in accordance with claim 1, wherein the connecting piece is a pedal of a motor vehicle.

3. A device in accordance with claim 1, wherein the transmission unit is designed as a push rod, which is connected with the connecting piece via a bolt and is guided linearly in said second baseplate so that the push rod follows the movement of said second baseplate.

4. A device in accordance with claim 1, wherein said compensating means comprises an elongated hole formed in the connecting piece, which elongated hole ensures an angle compensation between the transmission unit and the connecting piece during the actuation.

5. A device in accordance with claim 1, wherein one or more other connecting pieces are mounted rotatably by means of the mounting means of the pedal mechanism wherein said connecting pieces can be mounted on said second baseplate.

6. A device in accordance with claim 1, wherein said second baseplate and one or more additional upper baseplates can be mounted next to one another on said first baseplate in an articulated manner.

7. A device in accordance with claim 1, wherein said second baseplate is movable manually and/or mechanically by means of said drive unit after the release of the blocking unit.

8. A device in accordance with claim 1, wherein the blocking unit is embodied by a positive-locking and/or nonpositive self-locking of said drive unit.

9. A device in accordance with claim 1, wherein the adjustment of said second baseplate is performed by means of said drive unit, which moves said second baseplate in relation to said first baseplate either directly via a spindle drive or indirectly via a spindle drive, which is followed by a force amplifier in the form of a wedge.

10. A motor vehicle pedal mechanism, comprising:
a mounting arrangement;
a connecting piece mounted rotatably to said mounting arrangement;
a transmission unit coupled to the connecting piece for transmitting the movement of the connecting piece;
an adjusting mechanism for adjusting the position of said connecting piece;
one of a drive unit and a blocking unit for controlling or holding a position of the connecting piece;
a compensating means for compensating any changes in a position of said transmission unit that may be caused by an adjustment of a position of said connecting piece, said mounting arrangement including a lower baseplate, which is arranged stationarily, and an upper baseplate and said adjusting mechanism, which establishes an articulated connection between said lower baseplate and said upper baseplate, said upper baseplate being mounted pivotably on said lower baseplate, wherein a pivoting movement of said upper baseplate relative to said lower baseplate brings about a position adjustment of a position of said connecting piece.

11. A device in accordance with claim 10, wherein said connecting piece is a pedal of a motor vehicle.

12. A device in accordance with claim 10, wherein said transmission unit comprises a push rod connected with said connecting piece via a bolt and is guided linearly in said upper baseplate so that said push rod follows the movement of said upper baseplate.

13. A device in accordance with claim 10, wherein the compensating means comprises an elongated hole formed in said connecting piece, said elongated hole ensuring an angle compensation between said transmission unit and said connecting piece during adjustment of a position of said connecting piece.

14. A device in accordance with claim 10, wherein said connecting piece is a pedal of a motor vehicle and wherein said upper baseplate includes one or more sets of elevation connection parts for connection to an equal number of pedals.

15. A device in accordance with claim 10, wherein said mounting assembly has one or more upper baseplates mounted in an articulated manner next to one another on said lower baseplate.

16. A device in accordance with claim 10, wherein said one of a drive unit and a blocking unit move said upper baseplate mechanically by means of said drive unit or release said upper baseplate for manual movement after the release of said blocking unit.

17. A device in accordance with claim 16, wherein the blocking unit is embodied by a positive-locking and/or nonpositive self-locking of said drive unit.

18. A device in accordance with claim 10, wherein the adjustment of said upper baseplate is performed by means of said drive unit, which moves said upper second baseplate in relation to said lower first baseplate either directly via a spindle drive or indirectly via a spindle drive in cooperation with a force amplifier.

19. A device in accordance with claim 18, wherein said force amplifier is a wedge.
